(19) United States
(12) Patent Application Publication
(10) Pub. No.: US 2025/0357430 A1
(43) Pub. Date: Nov. 20, 2025

(54) SEMICONDUCTOR PACKAGES AND METHODS OF FORMING SAME

(71) Applicant: Taiwan Semiconductor Manufacturing Co., Ltd., Hsinchu (TW)

(72) Inventors: Ching-Yu Huang, Hsinchu (TW); Steven Sze Hang Poon, Hsinchu (TW)

(21) Appl. No.: 19/287,537

(22) Filed: Jul. 31, 2025

Related U.S. Application Data
(63) Continuation of application No. 18/437,969, filed on Feb. 9, 2024.
(60) Provisional application No. 63/584,554, filed on Sep. 22, 2023.

(51) Int. Cl. H01L 25/065; H01L 23/00; H01L 23/60

(52) U.S. Cl. CPC H01L 25/0657; H01L 23/60; H01L 24/05; H01L 24/13; H01L 2224/05022; H01L 2224/05025; H01L 2224/13025; H01L 2224/13026; H01L 2225/06513; H01L 2225/06541; H01L 2924/1431; H01L 2924/1434

(57) ABSTRACT

In an embodiment, a method includes: forming a first integrated circuit die, the first integrated circuit die comprising: a first active device along a first substrate; a first electrostatic discharge well along the first substrate; a first bonding pad over the first substrate and electrically connected to the first active device; and a first lightning conductor over the first substrate and electrically connected to the first electrostatic discharge well; forming a second integrated circuit die, the second integrated circuit die comprising: a second active device along a second substrate; a second electrostatic discharge well along the second substrate; a second bonding pad over the second substrate and electrically coupled to the second active device; and a second lightning conductor over the second substrate and electrically connected to the second electrostatic discharge well; and bonding the first integrated circuit die to the second integrated circuit die.

### PRIORITY CLAIM AND CROSS-REFERENCE

This application is a continuation of U.S. patent application Ser. No. 18/437,969, filed Feb. 9, 2024, which application claims the benefit of U.S. Provisional Application No. 63/584,554, filed on Sep. 22, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a trend for smaller and more creative packaging techniques of semiconductor dies has emerged. An example of such packaging systems is Package-on-Package (POP) technology. In a POP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1D illustrate cross-sectional views of intermediate steps during a process for forming an integrated circuit die, in accordance with some embodiments.

FIGS. 2A through 2D illustrate cross-sectional views of intermediate steps during a process for forming an integrated circuit die, in accordance with some embodiments.

FIGS. 3 through 4 illustrate cross-sectional views of intermediate steps during a process for forming a semiconductor package, in accordance with some embodiments.

FIGS. 5 through 8 illustrate cross-sectional views of intermediate steps during a process for forming a semiconductor package, in accordance with some embodiments.

FIGS. 9 through 12 illustrate cross-sectional views of intermediate steps during a process for forming a semiconductor package, in accordance with some embodiments.

FIG. 13 illustrates a cross-sectional view of an intermediate step during a process for forming a semiconductor package, in accordance with some embodiments.

FIGS. 14-18 illustrate plan views of integrated circuit dies, in accordance with some embodiments.

FIGS. 19A-19D illustrate cross-sectional views of semiconductor packages that include multiple integrated circuit dies, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a semiconductor package is formed by bonding a first integrated circuit die to a second integrated circuit die. The integrated circuit dies may be formed with complementary lightning conductor features designed to attract electrostatic discharge during bonding and route the current through the integrated circuit dies to electrostatic discharge wells along respective semiconductor substrates. In some embodiments, the first integrated circuit die is singulated from a wafer before being attached to the second integrated circuit die (e.g., remaining in wafer form). The singulation process, for example, may cause electrostatic charges (e.g., positive charges) to accumulate on the first integrated circuit die. However, other fabrication steps may cause charges to accumulate on either of the integrated circuit dies. As the integrated circuit dies are moved toward each other during the bonding process, electrostatic discharge may occur, such as between the most proximal locations on each component. As such, the integrated circuit dies include lightning conductors which serve as the most proximal (or most electrically attractive) points of conductivity on each of the components. As a result, electrostatic discharge will occur between the lightning conductors, which thereby prevents electrostatic discharge from occurring with conductive features that are electrically connected to the integrated circuits of the integrated circuit dies. The resulting semiconductor packages may be formed with greater yield and improved reliability due to the integrated circuits avoiding damage or shorting from electrostatic discharges. In addition, directing electrostatic discharge to specific locations allows for fewer electrostatic discharge wells to be required within the integrated circuits of the integrated circuit dies, thereby allowing more area along the semiconductor substrate to be used for active devices, through vias, or other features.

Various embodiments are described below in a particular context. Specifically, a chip on wafer (CoW) type system on an integrated chip (SoIC) package is described. However, various embodiments may also be applied to other types of semiconductor packaging technologies, such as, integrated fan-out (InFO) packages, or the like. Embodiments are discussed below wherein a first integrated circuit die (e.g., in the form of a singulated die) is attached to a second integrated circuit die (e.g., in the form of a wafer). It should be appreciated that the first integrated circuit die may remain in wafer form, while the second integrated circuit die is in singulated die form. In addition, the first and second integrated circuit dies may be attached to one another while both are in wafer forms or both in singulated die forms.

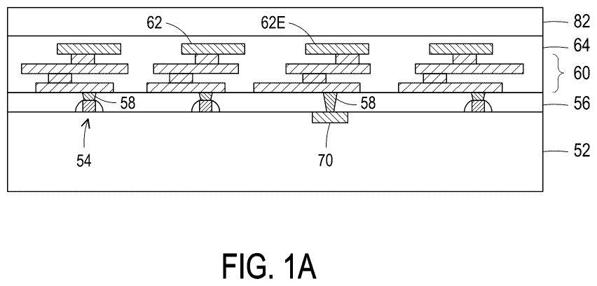

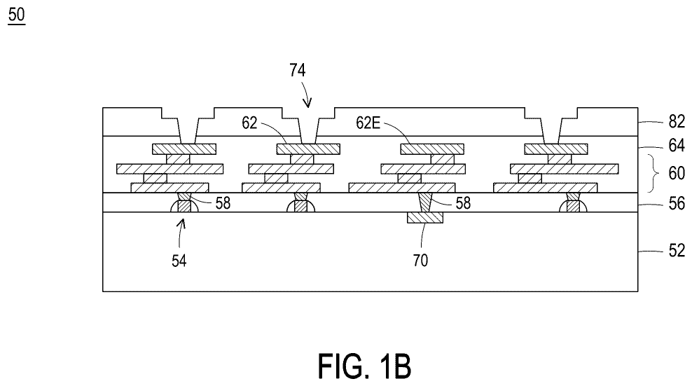

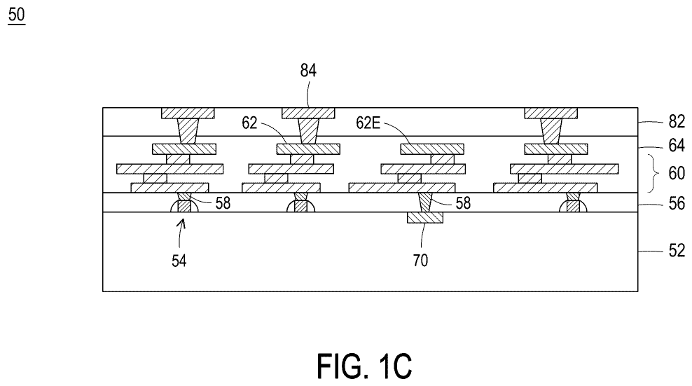

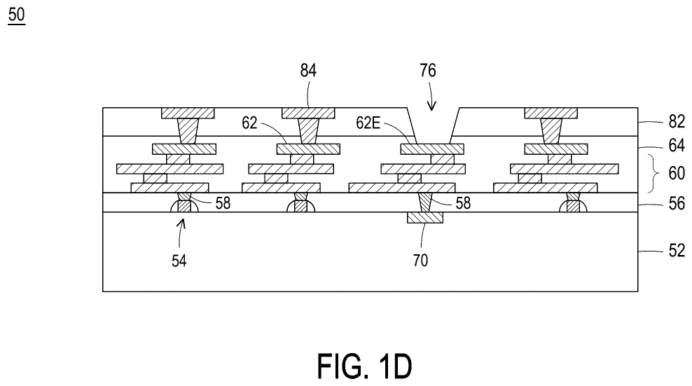

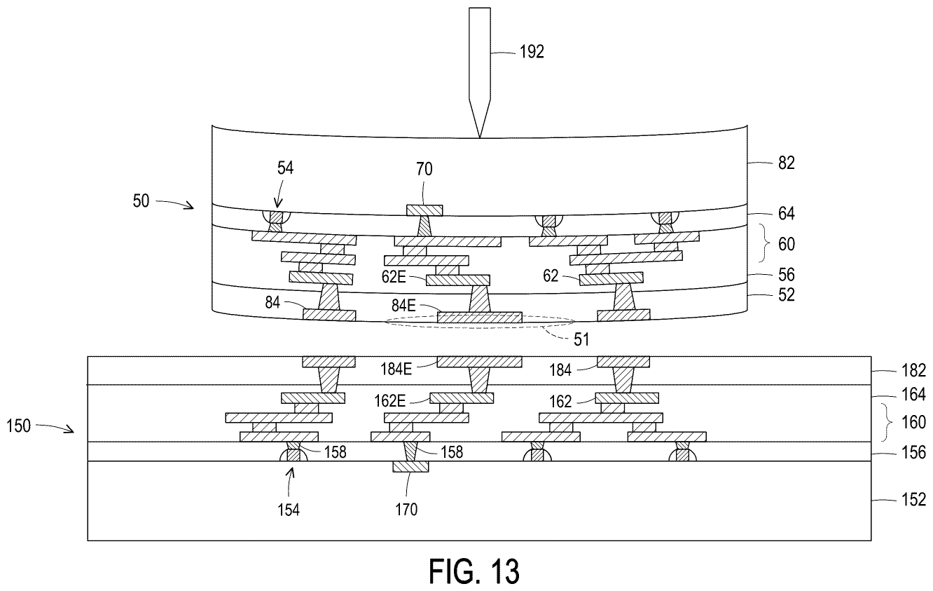

FIGS. 1A through 12 illustrate intermediate steps in the formation and bonding of integrated circuit dies 50/150 to one another, wherein each of the integrated circuit dies includes a lightning conductor (e.g., an electrostatic discharge conductor) for electrostatic discharge. In particular, at least one of the integrated circuit dies 50/150 includes a protruding lightning conductor, while the other of the integrated circuit dies 50/150 includes an inset or planar lightning conductor (e.g., being coplanar with bonding pads). FIGS. 13 through 18 illustrate other embodiments of the integrated circuit dies 50/150, wherein each of the integrated circuit dies 50/150 includes a planar lightning conductor. In particular, a sub-step of the bonding process that includes, e.g., movement of the integrated circuit die 50 toward the integrated circuit die 150, further includes causing a bowing of a central region of the integrated circuit die 50 toward the integrated circuit die 150. As a result, during this sub-step, the planar lightning conductor of the integrated circuit die is effectively protruding.

FIGS. 1A through 1D describe intermediate steps in the formation of a first integrated circuit die 50 (e.g., a first die), which includes forming an integrated circuit over a substrate as well as a bonding structure and a lightning conductor structure over the integrated circuit. FIG. 1A illustrates the integrated circuit of the first integrated circuit die 50, in accordance with some embodiments. The integrated circuit die 50 will be further processed and packaged into a semiconductor package. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

The integrated circuit die 50 may be formed at wafer level, which may include different device regions that are singulated in subsequent steps to form a plurality of integrated circuit dies. The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1A), sometimes called a front side, and an inactive surface (e.g., the surface facing downwards in FIG. 1A), sometimes called a back side.

Devices (represented by transistors) 54 may be formed at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

In accordance with various embodiments, electrostatic discharge (ESD) wells 70 (e.g., discharge wells) are formed along the semiconductor substrate 52. The ESD wells 70 may be formed before, after, or during formation of the active devices. For example, the ESD well 70 may be formed by implanting a region of the semiconductor substrate 52 with a first conductivity type (e.g., p-type) at a desired depth and then implanting that region with a second conductivity type (e.g., n-type) at a lesser depth. Note that the first and second conductivity types are opposite of each other and may be the reverse of the example above. In other embodiments, some of the devices 54 (e.g., field effect transistors, such as MOSFETs) may be utilized as ESD wells 70.

Conductive plugs 58 extend through the ILD 56 to electrically and physically couple the devices 54 and the ESD wells 70. For example, when the devices 54 are transistors, the conductive plugs 58 may couple the gates and source/drain regions of the transistors. Similarly, some of the conductive plugs 58 may extend to the ESD wells 70 within the substrate or to the transistors that may be used as ESD wells 70. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The first integrated circuit die 50 further includes pads 62, such as aluminum pads, to which external connections are made. The pads 62 are on the active side of the first integrated circuit die 50, such as in and/or on the interconnect structure 60. One or more passivation films 64 are on the integrated circuit die 50, such as on portions of the interconnect structure 60 and pads 62.

In accordance with various embodiments, the pads 62 include one or more pads 62E which are electrically connected to the ESD wells 70 through the interconnect structure 60. In addition, the pad 62E may be electrically isolated from the integrated circuit of the integrated circuit die 50, such as being electrically isolated from the devices 54. In some embodiments, a single or multiple pads 62E may be connected to a plurality of the ESD wells 70.

In some embodiments, some of the pads 62 that are electrically connected to the devices 54 may be used as test pads before additional processing steps are performed. For example, the pads 62 may be probed as part of a wafer-acceptance-test, a circuit test, a Known Good Die (KGD) test, or the like. The probing may be performed to verify the functionality of the devices 54 (e.g., active or passive devices), other electrical components, or various electrical connections within the integrated circuit. For example, the probing may be performed by contacting a probe needle (not specifically illustrated) to the metal pads 62. The integrated circuit dies 50 within the wafer that pass the circuit probe testing will be deemed KGDs and may be utilized in further processing after a subsequent singulation process.

After performing the circuit probe testing, a bonding layer 82 may be formed over the pads 62 and the interconnect structure 60. The bonding layer 82 may be any material suitable for achieving a dielectric-to-dielectric bond. For example, the bonding layer 82 may comprise silicon oxide, silicon nitride, silicon oxynitride, or the like, and the bonding layer 82 may be deposited using a suitable deposition process such as PVD, CVD, ALD, or the like.

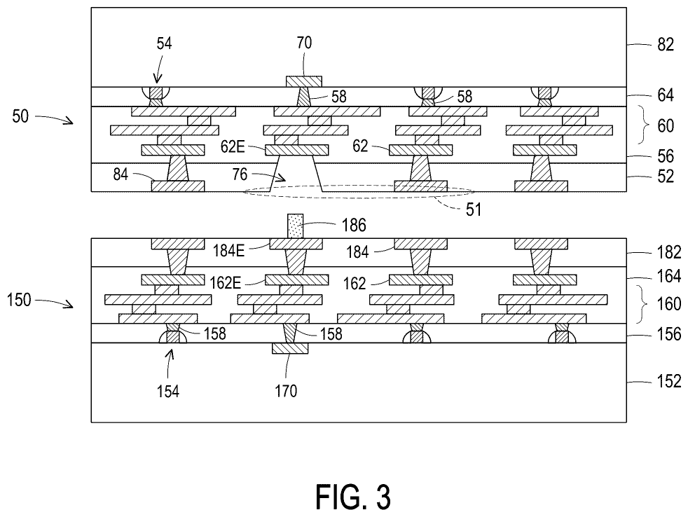

FIGS. 1B through 1D illustrate formation of bonding pads 84 and a lightning conductor structure through the bonding layer 82 and the passivation films 64. The bonding pads 84 may also be used to attach the integrated circuit die 50 to another semiconductor component (see, e.g., FIG. 3). As discussed in greater detail below, the lightning conductor structure may contribute to attachment of the other semiconductor component.

In FIG. 1B, openings 74 are formed in the bonding layer 82 and the passivation film 64 to expose underlying pads 62. In some embodiments, the openings 74 may extend past the pads 62 to expose upper features of the interconnect structure 60. As illustrated, the openings 74 may expose the pads 62 that are connected to the active devices and integrated circuit of the integrated circuit die 50. Conversely, the pads 62E that are electrically connected to the ESD wells 70 may remain covered by the passivation films 64 and the bonding layer 82. The openings 74 may be patterned in the bonding layer 82 and the passivation film 64 using photolithography or any suitable method. For example, the openings 74 may be patterned with multiple photo-masking steps and etching steps in order to form the illustrated shapes of the openings 74.

In FIG. 1C, bonding pads 84 are formed in the openings 74 within the bonding layer 82. The bonding pads 84 are formed for external connection to the pads 62 and/or the interconnect structure 60. As illustrated, the bonding pads 84 may be disposed in the bonding layer 82 and extend partially through the passivation films 64. The bonding pads 84 have landing pad portions on and extending along the major surface of the bonding layer 82, and have via portions extending through the bonding layer 82 (and the passivation film 64) to physically and electrically couple the pads 62. The bonding pads 84 are formed of a similar material and using similar processes as described above with respect to the interconnect structure 60. A planarization step may then be performed to substantially level surfaces of the bonding pads 84 and the bonding layer 82. Although formation of the bonding pads 84 are described in a dual damascene process, the via portions and the landing pad portions of the bonding pads 84 may be formed in separate processes, such as single damascene processes.

In FIG. 1D, one or more openings 76 is formed through the bonding layer 82 and partially through the passivation film 64 to expose the pads 62E. The opening 76 may be patterned in the bonding layer 82 and the passivation film 64 using photolithography or any suitable method, similarly as described above in connection with the openings 74. For example, formation of the opening 76 may include a single photo-masking and etching step. As discussed in greater detail below, the opening 76 in conjunction with the underlying pad 62E may collectively form a lightning conductor (e.g., an inset lightning conductor).

In some embodiments, a singulation process is performed to separate the integrated circuit die 50 from other integrated circuit dies 50 within the wafer. The singulated integrated circuit dies 50 (e.g., the KGDs among the integrated circuit dies 50) will be attached to other semiconductor components as discussed below in greater detail. In some embodiments, the integrated circuit dies 50 may remain in wafer form and attached to the other semiconductor components in either die or wafer form.

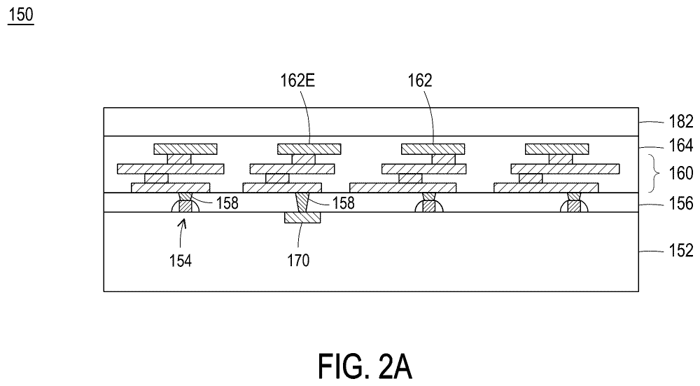

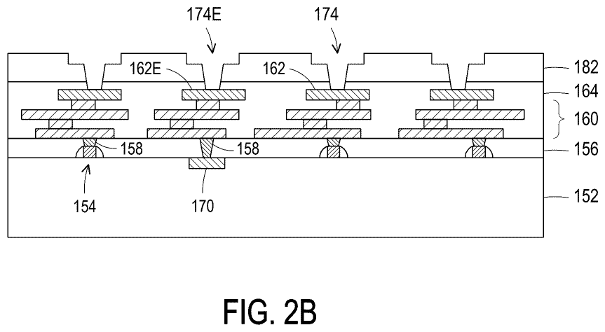

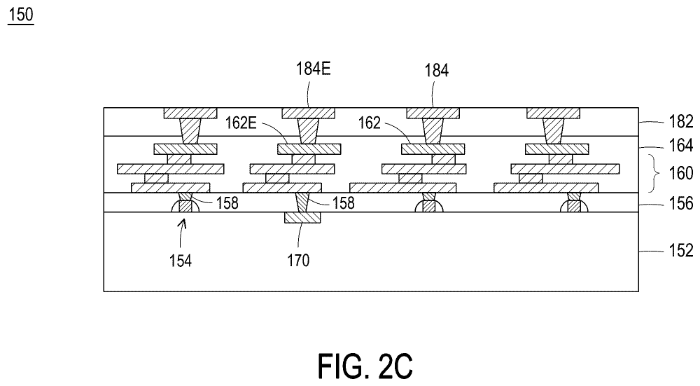

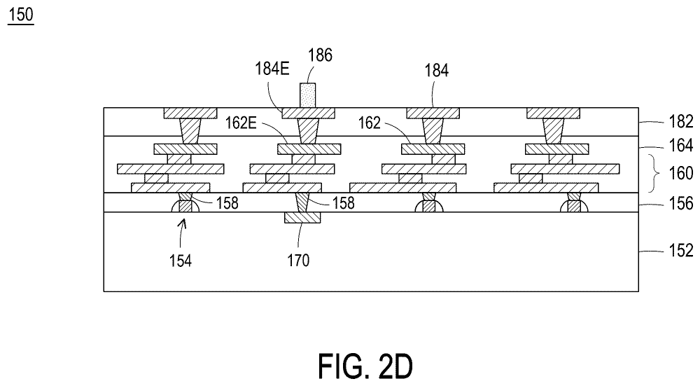

FIGS. 2A through 2D describe intermediate steps in the formation of a second integrated circuit die 150 (e.g., a second die), which includes forming an integrated circuit over a substrate as well as a bonding structure and a lightning conductor structure over the integrated circuit. FIG. 2A illustrates the integrated circuit of the integrated circuit die 150, in accordance with some embodiments. The integrated circuit die 150 will be packaged with the integrated circuit die 50 in subsequent processing to form a semiconductor package. The integrated circuit die 150 may be a logic die (e.g., CPU, GPU, SoC, application processor (AP), microcontroller, etc.), a memory die (e.g., DRAM die, SRAM die, etc.), a power management die (e.g., PMIC die), a radio frequency (RF) die, a sensor die, a MEMS die, a signal processing die (e.g., DSP die), a front-end die (e.g., AFE die), the like, or combinations thereof. In some embodiments, the integrated circuit die 150 is a same type as the integrated circuit die 50. In other embodiments, the integrated circuit die 150 is a memory die while the integrated circuit die 50 is a logic die, or vice versa. Any suitable combination may be used.

The illustrated features of the integrated circuit die 150 may be analogous to the illustrated features of the integrated circuit die 50. As such, the features of the integrated circuit die 150 may be labeled with the same numbers albeit with the number “1” in the hundreds place. Similarly as with the integrated circuit die 50, the integrated circuit die 150 may undergo circuit probe testing to identify the known good dies (KGDs). In embodiments in which the integrated circuit die 150 remains in wafer form during attachment of the integrated circuit dies 50, dummy dies or integrate circuit dies 50 that failed the circuit probe testing may be attached to the integrated circuit dies 150 that also failed the circuit probe testing. After performing the circuit probe testing, an additional passivation film 164 (if necessary) and a bonding layer 182 may be formed over the passivation films 164.

In FIG. 2B, openings 174 are formed through the bonding layer 182 and the passivation layer 164 to expose the pads 162, similarly as described above in connection with the openings 74 (see FIG. 1B). For example, the openings 174 may be formed through one or more patterning and etching steps. Note that the opening 174E exposes the pad 162E (e.g., electrically connected to the ESD wells 170).

In FIG. 2C, bonding pads 184 are formed in the openings 174, similarly as described above in connection with the bonding pads 84 (see FIG. 1C). Note that the bonding pad 184E is formed in the opening 174E, and the bonding pad 184E is therefore electrically connected to the ESD wells 170. A planarization process may be performed resulting in the bonding pads 184 and the bonding layer 182 being substantially coplanar within process variations.

In FIG. 2D, a pillar 186 is formed on the bonding pad 184E, while other bonding pads 184 remain free of pillars 186. For example, a mask (not specifically illustrated) may be formed over the integrated circuit die 150 and patterned to have an opening over the bonding pad 184E. Conductive material may then be deposited in the opening, and the mask is removed afterward. In some embodiments, the pillar 186 may be solder free and have substantially vertical sidewalls. In addition, a metal cap layer may be formed on the top of the pillar 186. The metal cap layer may include nickel, tin, tin-lead, gold, silver, palladium, indium, nickel-palladium-gold, nickel-gold, the like, or a combination thereof and may be formed by a plating process. In accordance with various embodiments, a height of the pillar 186 is less than or equal to a depth of the opening 76. The bonding pad 184E in conjunction with the pillar 186 may collectively form a lightning conductor (e.g., a protruding lightning conductor). This protruding lightning conductor corresponds to the inset lightning conductor (e.g., the opening 76 and the pad 62E) in a bonding step discussed below.

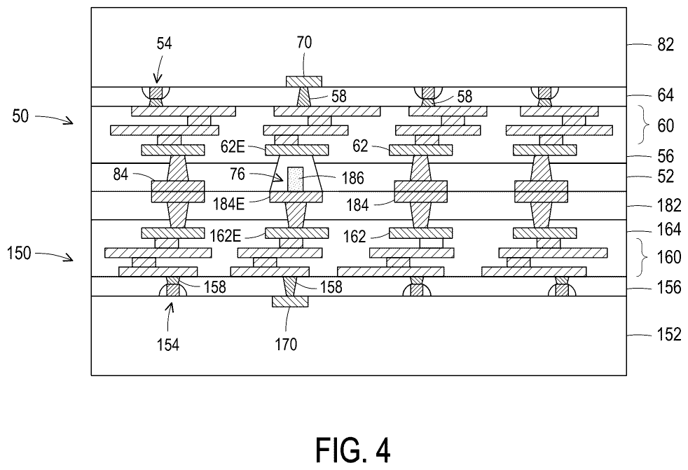

FIGS. 3 through 4 illustrate cross-sectional views of intermediate steps during attachment of the integrated circuit die 50 to the integrated circuit die 150 to form a semiconductor package. In accordance with various embodiments, the integrated circuit die 150 remains in wafer form for attachment to the integrated circuit die 50. Although one integrated circuit die 50 is illustrated, more than one integrated circuit die 50 may be attached to form the semiconductor package.

For example, the integrated circuit die 50A is bonded to the integrated circuit die 150A through the bonding pads 84/184 and the bonding layers 82/182. Either of the integrated circuit dies 50A/150A may be a logic device or a memory device as described above. In some embodiments, the integrated circuit dies 50A/150A may be the same type of dies, such as SoC dies. The integrated circuit dies 50A/150A may be formed in processes of a same technology node, or may be formed in processes of different technology nodes. For example, the integrated circuit die 150A may be of a more advanced process node than the integrated circuit die 50A, or vice versa. Other combinations of the integrated circuit dies 50A/150A may be utilized.

The integrated circuit die 50A is bonded to the integrated circuit die 150A, for example, in a dielectric-to-dielectric and metal-to-metal bonding configuration. The integrated circuit die 50A is disposed face down such that the front side of the integrated circuit die 50A faces the front side of the integrated circuit die 150A. The bonding layer 82 of the integrated circuit die 50A may be directly bonded to the bonding layer 182 of the integrated circuit die 150A, and the bonding pads 84 of the integrated circuit die 50A may be directly bonded to the bonding pads 184 of the integrated circuit die 150A. In an embodiment, the bonds between the bonding layer 82 and the bonding layer 182 are dielectric-to-dielectric (e.g., oxide-to-oxide) bonds, or the like. The bonding process also directly bonds the bonding pads 84 to the bonding pads 184 through direct metal-to-metal bonding. Thus, electrical connection between the integrated circuit die 50A and the integrated circuit die 150A is provided by the physical and electrical connection of the bonding pads 84 and the bonding pads 184. In some embodiments, the interface also includes dielectric-to-metal interfaces between the integrated circuit dies 50A/150A (e.g., where the bonding pads 84 and the bonding pads 184 are not perfectly aligned and/or have different widths).

Still referring to FIGS. 3 and 4, the bonding process starts with applying a surface treatment to one or both of the respective bonding layers 82/182. The surface treatment may include a plasma treatment. The plasma treatment may be performed in a vacuum environment. After the plasma treatment, the surface treatment may further include a cleaning process (e.g., a rinse with deionized water, or the like) that may be applied to one or both of the bonding layers 82/182.

The bonding process may then proceed to aligning the bonding pads 84 of the integrated circuit die 50A to the bonding pads 184 of the integrated circuit die 150A. The integrated circuit die 50A may first be secured to a chuck (not specifically illustrated) using vacuum or a suitable means. When the integrated circuit dies 50A/150A are aligned, the bonding pads 84 may overlap with the corresponding bonding pads 184. After alignment, the integrated circuit dies 50A/150A are moved toward one another (e.g., the integrated circuit die 50A is moved downward toward the integrated circuit die 150).

As the integrated circuit dies 50A/150A move closer to one another, electrostatic charges on one or both may cause electric discharge between the two components. The electrostatic charges may have accumulated during previous processing steps, such as during the singulation of the integrated circuit dies 50A. For example, the singulation process may cause a buildup of positive charges on the integrated circuit die 50A, which may discharge when placed in close proximity with the integrated circuit die 150A which may have areas of negative or neutral charge.

The pillar 186 may serve as a lightning conductor with the pad 62E to route the electrostatic discharge to the ESD wells 170 of the integrated circuit die 150A and the ESD wells 70 of the integrated circuit die 50A. Similarly, the pad 62E in conjunction with the opening 76 may also serve as a lightning conductor for the electrostatic discharge. As the integrated circuit dies 50A/150A move closer and eventually physically contact one another, the pillar 186 fits within the opening 76. As a result, the bonding layers 82/182 and the bonding pads 84/184 are able to form a seamless interface when the integrated circuit die 50A is bonded to the integrated circuit die 150A.

The bonding includes a pre-bonding step, during which the integrated circuit die 50A is put in contact with the bonding layer 182 and the bonding pads 184. In some embodiments, the vacuum or other means of securing the integrated circuit die 50A to the chuck may be adjusted so that a central region 51 of the integrated circuit die 50A bows outward (e.g., downward as illustrated) toward the integrated circuit die 150A (see, e.g., FIG. 13). In addition or alternatively, a pin may press against the back side of the integrated circuit die 50A to cause the bowing toward the integrated circuit die 150A. The pre-bonding may be performed at room temperature (e.g., between about 21° C. and about 25° C.). The bonding process continues with performing an anneal, for example, at a temperature between about 150° C. and about 400° C. for a duration between about 0.5 hours and about 3 hours, so that the metal of the bonding pads 84 (e.g., copper) and the metal of the bonding pads 184 (e.g., copper) inter-diffuses with each other, and hence the direct metal-to-metal bonding is formed. Other direct bonding processes (e.g., using adhesives, polymer-to-polymer bonding, or the like) may be used in other embodiments. Notably, the integrated circuit die 50A is bonded to the integrated circuit die 150A without the use of solder connections (e.g., microbumps or the like).

As discussed above, the height of the pillar 186 may be the same or less than the depth of the opening 76. In some embodiments, after the bonding process, the pillar 186 makes physical contact with the pad 62E. As a result, the ESD wells 70 maintain electrical connection with the ESD wells 170 to continue assisting in charge balancing if necessary. In addition, because the pillar 186 may not completely fill the opening 76, a void around the pillar 186 may have the shape of a ring. In embodiments in which the height of the pillar 186 is less than the depth of the opening 76, after the bonding process, the pillar 186 remains separated from the pad 62E by a gap. The gap may insulate the ESD wells 70/170 from having a direct electrical connection, and the pillar 186 and the pad 62E may continue to provide electrostatic discharge benefits if necessary. In addition, the void in the opening 76 and around the pillar 186 may have a dome shape.

Following the attachment process, the semiconductor package may undergo further processing (not specifically illustrated). For example, a gap-fill material may be formed over and between adjacent integrated circuit dies 50A, additional semiconductor components may be attached to the semiconductor package, external connectors may be formed, and/or the semiconductor package may be attached to a package substrate. At any stages, the structure may undergo additional testing (e.g., thermal cycle testing).

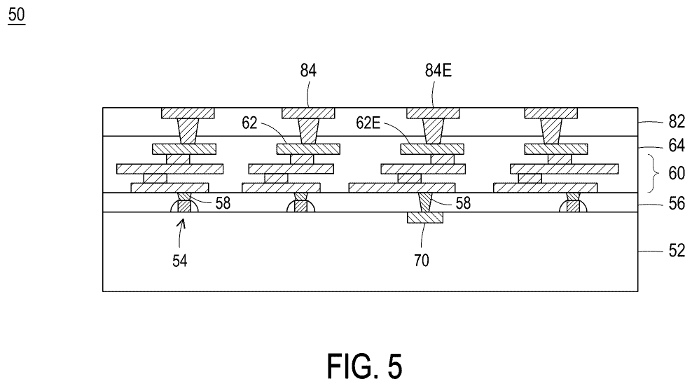

FIGS. 5 through 8 illustrate formation of another semiconductor package, in accordance with various embodiments. Formation of the semiconductor package includes forming integrated circuit dies 50B/150B and attaching them to one another, similarly as described above unless otherwise stated. In particular, the integrated circuit die 150B is formed to include a solder ball, which serves as a lightning conductor during attachment of the integrated circuit die 50B to the integrated circuit die 150B.

In FIG. 5, an integrated circuit die 50B is formed to include most of the same features as the integrated circuit die 50A described above (see FIGS. 1A through 1D). However, the opening 76 over the pad 62E is not formed, and instead the opening 74E is formed over the pad 62E with a bonding pad 84E formed therein (e.g., which is electrically connected to the ESD wells 70). The opening 74E and the bonding pad 84E are formed simultaneously with the other openings 74 and bonding pads 84, similarly as described above. As a result, formation of the integrated circuit die 50B may include fewer steps than formation of the integrated circuit die 50A. In some embodiments, the integrated circuit die 50B is then singulated from a wafer. As discussed above, the singulation process may contribute to accumulation of electrostatic charges on the integrated circuit die 50B. The bonding pad 84E may form a planar lightning conductor.

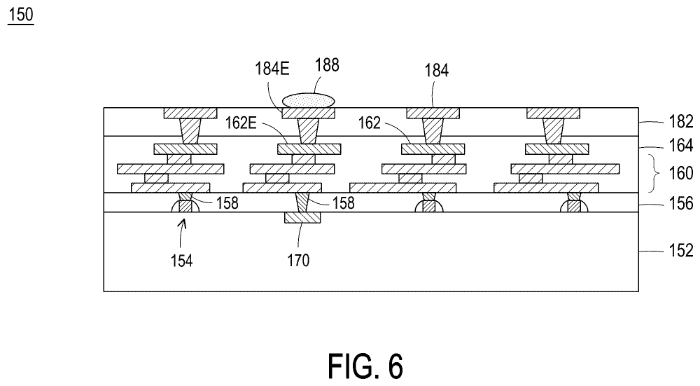

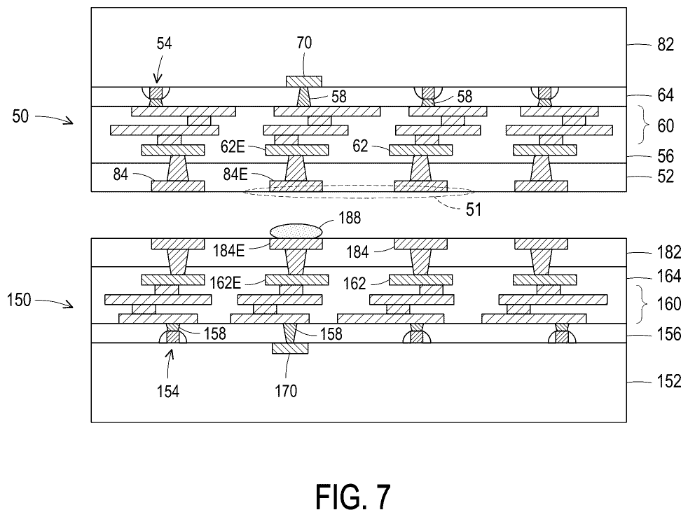

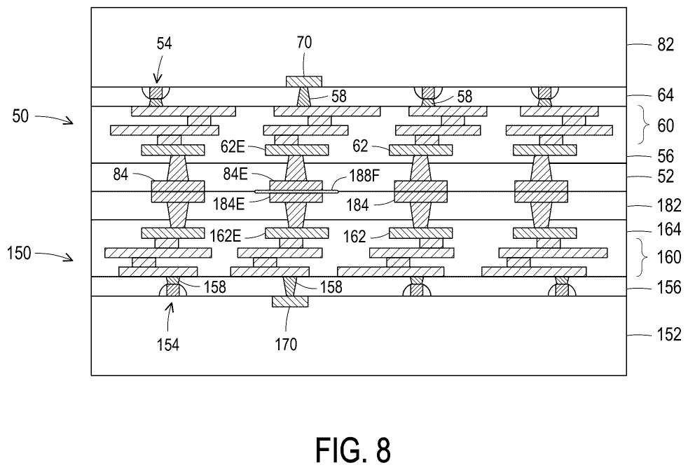

In FIG. 6, an integrated circuit die 150B is formed to include most of the same features as the integrated circuit die 150A described above (see FIGS. 2A through 2D). However, a solder ball 188 (e.g., instead of the pillar 186) is deposited on the bonding pad 184E (e.g., which is electrically connected to the ESD wells 170). In a subsequent attachment process (see FIGS. 7 through 8), the solder ball 188 will serve as a lightning conductor to facilitate electrostatic discharge between the integrated circuit dies 50B/150B.

In some embodiments, a mask (not specifically illustrated) may be formed or placed over the integrated circuit die 150B, and the solder ball 188 may be deposited onto the bonding pad 184E through an opening in the mask. In some embodiments, the solder ball 188 may be deposited onto the bonding pad 184E without the use of a mask. The solder ball 188 may be formed by initially forming a layer of solder through evaporation, electroplating, printing, solder transfer, ball placement, or the like. Optionally, once a layer of solder has been formed on the structure, a reflow may be performed in order to shape the material into the desired bump shape. The bonding pad 184E in conjunction with the solder ball 188 may collectively form a protruding lightning conductor.

FIGS. 7 through 8 illustrate cross-sectional views of intermediate steps during attachment of the integrated circuit die 50B to the integrated circuit die 150B. In accordance with various embodiments, the integrated circuit die 150B remains in wafer form for attachment to the integrated circuit die 50B (e.g., a singulated die). Although one integrated circuit die 50B is illustrated, more than one integrated circuit die 50B may be attached to form the semiconductor package.

For example, the integrated circuit die 50B is bonded to the integrated circuit die 150B through the bonding pads 84/184 and the bonding layers 82/182. Either of the integrated circuit dies 50B/150B may be a logic device or a memory device as described above. In some embodiments, the integrated circuit dies 50B/150B may be the same type of dies, such as SoC dies. The integrated circuit dies 50B/150B may be formed in processes of a same technology node, or may be formed in processes of different technology nodes. For example, the integrated circuit die 150B may be of a more advanced process node than the integrated circuit die 50B, or vice versa. Other combinations of the integrated circuit dies 50B/150B may be utilized.

The integrated circuit die 50B is bonded to the integrated circuit die 150B, for example, in a dielectric-to-dielectric and metal-to-metal bonding configuration, similarly as described above in connection with the integrated circuit dies 50A/150A (see FIGS. 3 through 4). The integrated circuit die 50B is disposed face down such that the front side of the integrated circuit die 50B faces the front side of the integrated circuit die 150B. The bonding layer 82 of the integrated circuit die 50B may be directly bonded to the bonding layer 182 of the integrated circuit die 150B, and the bonding pads 84 of the integrated circuit die 50B may be directly bonded to the bonding pads 184 of the integrated circuit die 150B. In an embodiment, the bonds between the bonding layer 82 and the bonding layer 182 are dielectric-to-dielectric (e.g., oxide-to-oxide) bonds, or the like. The bonding process also directly bonds the bonding pads 84 to the bonding pads 184 through direct metal-to-metal bonding. Thus, electrical connection between the integrated circuit die 50B and the integrated circuit die 150B is provided by the physical and electrical connection of the bonding pads 84 and the bonding pads 184. In some embodiments, the interface also includes dielectric-to-metal interfaces between the integrated circuit dies 50B/150B (e.g., where the bonding pads 84 and the bonding pads 184 are not perfectly aligned and/or have different widths).

Moreover, the interface between the integrated circuit dies 50B/150B includes metal-to-metal bonds between the solder ball 188 and the bonding pad 84E of the integrated circuit die 50B. As discussed in greater detail below, during the bonding process, the solder ball 188 is reflowed, which may cause the solder ball 188 to spread out on contact with the integrated circuit die 50B. As a result, the flattened solder ball 188 directly interposes the bonding pads 84E/184E. In some embodiments, the flattened solder ball 188 may spread out beyond widths of the bonding pads 84E/184E and, therefore, directly interpose portions of the bonding layers 82/182. In other embodiments, the flattened solder ball 188 may remain within the widths of the bonding pads 84/184.

Still referring to FIGS. 7 and 8 and similarly as described above, the bonding process may start with a surface treatment and cleaning process performed on the integrated circuit dies 50B/150B. Next, the bonding process proceeds by aligning the bonding pads 84 to the bonding pads 184. When the integrated circuit dies 50B/150B are aligned, the bonding pads 84 may overlap with the corresponding bonding pads 184. After alignment, the integrated circuit dies 50B/150B are moved toward one another (e.g., the integrated circuit die 50B is moved downward toward the integrated circuit die 150B). In some embodiments, before moving the integrated circuit die 50B, a heat may be applied to soften or partially reflow the solder ball 188, which may change shape or remain in substantially the same shape. As the integrated circuit dies 50B/150B move closer to one another, electrostatic charges on one or both may cause electric discharge between the two components. As discussed above, the electrostatic charges may have accumulated during previous processing steps, such as during the singulation of the integrated circuit dies 50B.

The solder ball 188 serves as a lightning conductor with the bonding pad 84E to route the electrostatic discharge to the ESD wells 170 of the integrated circuit die 150B and the ESD wells 70 of the integrated circuit die 50B. Similarly, the bonding pad 84E may also serve as a lightning conductor due to bowing of the integrated circuit die 50B causing the bonding pad 84E to be the closest conductive feature to the solder ball 188 of the integrated circuit die 150B during approach. As the integrated circuit dies 50B/150B move closer, the solder ball 188 of the integrated circuit die 150B is first to make physical contact with the bonding pad 84E of the integrated circuit die 50B. As the integrated circuit dies 50B/150B continue moving toward one another, the solder ball 188 flattens and spreads out along the bonding pads 84E/184E. In accordance with some embodiments, the solder ball 188 is deposited at a volume such that the flattened solder ball 188 may have a thickness small enough to allow direct bonding between the bonding pads 84/184. As a result, the bonding layers 82/182 and the bonding pads 84/184 may form a substantially seamless interface when the integrated circuit die 50B is bonded to the integrated circuit die 150B.

The bonding includes a pre-bonding step, during which the integrated circuit die 50B is put in contact first with the solder ball 188 and, next, with the bonding layer 182 and the bonding pads 184. The integrated circuit die 50B may be secured to a chuck by a vacuum or any suitable means, similarly as described above in connection with the integrated circuit die 50A. In addition, a pin may press against the back side of the integrated circuit die 50B to cause a bowing toward the integrated circuit die 150B. The pre-bonding may be performed at room temperature (e.g., between about 21° C. and about 25° C.). The bonding process continues with performing an anneal, for example, at a temperature between about 150° C. and about 400° C. for a duration between about 0.5 hours and about 3 hours, so that the metal of the bonding pads 84 (e.g., copper) and the metal of the bonding pads 184 (e.g., copper) inter-diffuses with each other, and hence the direct metal-to-metal bonding is formed. Other direct bonding processes (e.g., using adhesives, polymer-to-polymer bonding, or the like) may be used in other embodiments. Notably, the solder ball 188 connections with the bonding pads 84E/184E assist in the bonding of the integrated circuit die 50B to the integrated circuit die 150B.

As discussed above, the volume of the solder ball 188 will have an effect on the size of the flattened solder ball 188 after the bonding process. In some embodiments, after the bonding process, the solder ball 188 is directly interposed and in physical contact with the bonding pads 84E/184E. As a result, the ESD wells 70 maintain electrical connection with the ESD wells 170 to continue assisting in charge balancing if necessary. As discussed above, the flattened solder ball 188 may improve adhesion of the integrated circuit dies 50B/150B with stronger bonds with each of the bonding pads 84E/184E.

Following the attachment process, the semiconductor package may undergo further processing (not specifically illustrated). For example, a gap-fill material may be formed over and between adjacent integrated circuit dies 50B, additional semiconductor components may be attached to the semiconductor package, external connectors may be formed, and/or the semiconductor package may be attached to a package substrate. At any stages, the structure may undergo additional testing (e.g., thermal cycle testing).

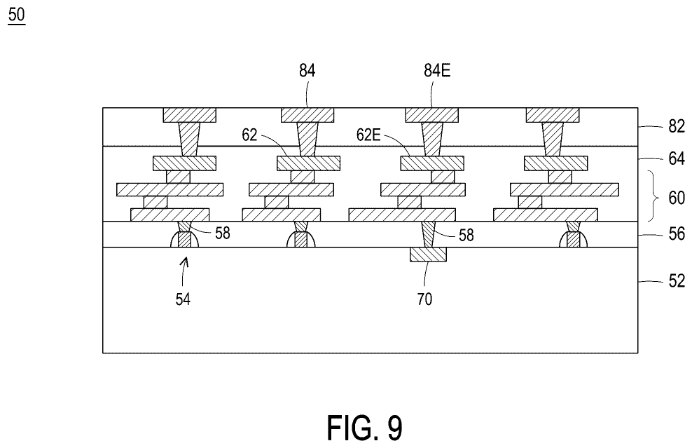

FIGS. 9 through 12 illustrate formation of another semiconductor package, in accordance with various embodiments. Formation of the semiconductor package includes forming integrated circuit dies 50C/150C and attaching them to one another, similarly as described above unless otherwise stated. In particular, the integrated circuit die 150C is formed with a recessed bonding pad 184E and a solder pillar 190 formed thereon, which serves as a lightning conductor during attachment of the integrated circuit die 50C to the integrated circuit die 150C.

In FIG. 9, an integrated circuit die 50C is formed to include most of the same features as the integrated circuit dies 50A/50B described above (see FIGS. 1A through 1D and 5). However, the opening 76 over the pad 62E is not formed, and instead the opening 74E is formed over the pad 62E with a bonding pad 84E formed therein (e.g., which is electrically connected to the ESD wells 70). The opening 74E and the bonding pads 84E are formed simultaneously with the other openings 74 and bonding pads 84, similarly as described above. As a result, formation of the integrated circuit die 50C may include fewer steps than formation of the integrated circuit die 50A. In some embodiments, the integrated circuit die 50C is then singulated from a wafer. As discussed above, the singulation process may contribute to accumulation of electrostatic charges on the integrated circuit die 50C. The bonding pad 84E may form a planar lightning conductor.

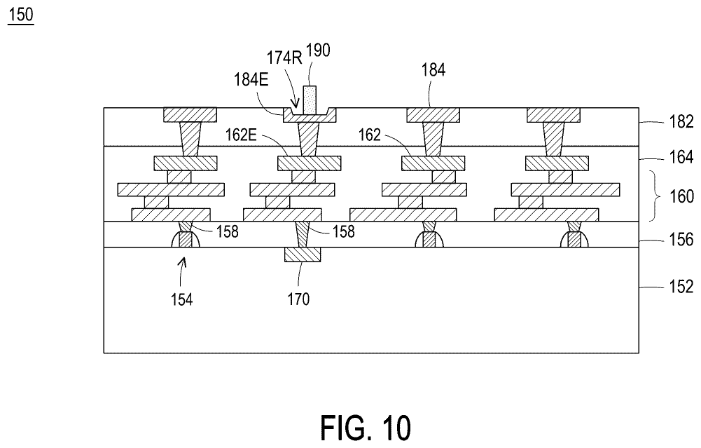

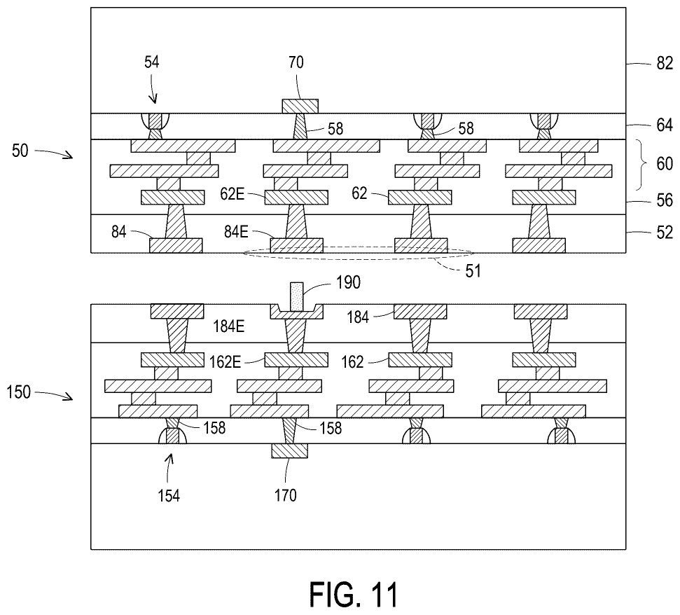

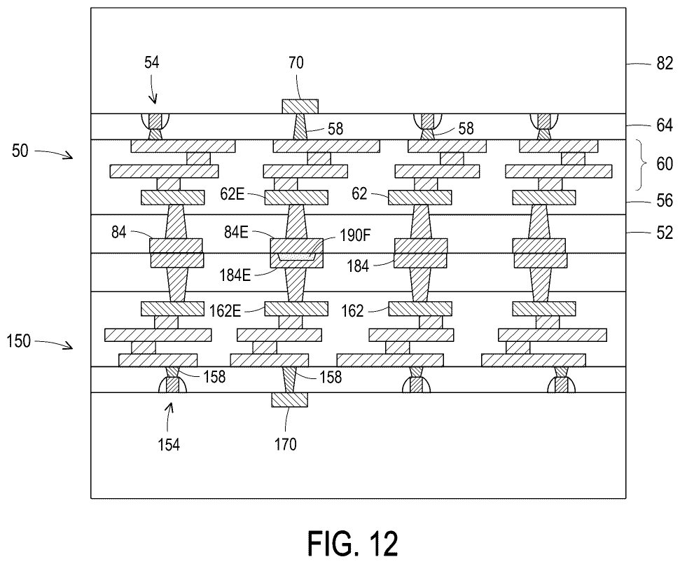

In FIG. 10, an integrated circuit die 150C is formed to include most of the same features as the integrated circuit dies 150A/150B described above (see FIGS. 2A through 2D and 6). In accordance with the present embodiments, formation of the bonding pads 184 is tuned to form the bonding pad 184E (e.g., electrically connected to the ESD wells 170) as being recessed compared to the other bonding pads 184. A solder pillar 190 is then deposited onto the recessed bonding pad 184E. In a subsequent attachment process (see FIGS. 11 through 12), the solder pillar 190 will serve as a lightning conductor to facilitate electrostatic discharge between the integrated circuit dies 50C/150C.

In some embodiments, formation of the bonding pads 184 is tuned to form the bonding pad 184E as being recessed from the bonding layer 182 while the other bonding pads 184 are substantially level with the bonding layer 182. For example, an upper surface of the recessed bonding pad 184E may have a dish or bowl shape. In some embodiments, this is accomplished by forming the landing pad portion of the bonding pad 184E to have different dimensions than the landing pad portions of the other bonding pads 184. For example, when forming the openings 174 (see FIG. 2B), the opening 174E that exposes the pad 162E may be patterned to have a greater volume (e.g., by having a greater width or by increasing other dimensions of the shape of the opening 174E) than the other openings 174 that expose the other pads 162. The conductive material for the bonding pads 184 may then be deposited in the openings 174 (and the opening 174E). The deposition may be halted when the openings 174 are filled and when the opening 174E is partially filled. The remaining unfilled portion of the opening 174E becomes a recess 174R.

After forming the openings 174E (see FIG. 2B), a solder pillar 190 is formed on the recessed bonding pad 184E. For example, a mask or a sacrificial material (not specifically illustrated) may be placed over the integrated circuit die 150C, and the solder pillar 190 may be deposited onto the recessed bonding pad 184E through an opening in the mask or sacrificial material. In embodiments with the sacrificial material, the sacrificial material may be patterned to form an opening and then removed after depositing the solder pillar 190 using a suitable method. In some embodiments, the solder pillar 190 is formed by sputtering, printing, electro plating, electroless plating, CVD, or the like. As illustrated, the resulting solder pillar 190 may have substantially straight and vertical sidewalls. The bonding pad 184E in conjunction with the solder pillar 190 may collectively form a protruding lightning conductor.

FIGS. 11 through 12 illustrate cross-sectional views of intermediate steps during attachment of the integrated circuit die 50C to the integrated circuit die 150C. In accordance with various embodiments, the integrated circuit die 150C remains in wafer form for attachment to the integrated circuit die 50C (e.g., a singulated die). Although one integrated circuit die 50C is illustrated, more than one integrated circuit die 50C may be attached to form the semiconductor package.

For example, the integrated circuit die 50C is bonded to the integrated circuit die 150C through the bonding pads 84/184 and the bonding layers 82/182. Either of the integrated circuit dies 50C/150C may be a logic device or a memory device as described above. In some embodiments, the integrated circuit dies 50C/150C may be the same type of dies, such as SoC dies. The integrated circuit dies 50C/150C may be formed in processes of a same technology node, or may be formed in processes of different technology nodes. For example, the integrated circuit die 150C may be of a more advanced process node than the integrated circuit die 50C, or vice versa. Other combinations of the integrated circuit dies 50C/150C may be utilized.

The integrated circuit die 50C is bonded to the integrated circuit die 150C, for example, in a dielectric-to-dielectric and metal-to-metal bonding configuration, similarly as described above in connection with the integrated circuit dies 50A/150A (see FIGS. 3 through 4). The integrated circuit die 50C is disposed face down such that the front side of the integrated circuit die 50C faces the front side of the integrated circuit die 150C. The bonding layer 82 of the integrated circuit die 50C may be directly bonded to the bonding layer 182 of the integrated circuit die 150C, and the bonding pads 84 of the integrated circuit die 50C may be directly bonded to the bonding pads 184 of the integrated circuit die 150C. In an embodiment, the bonds between the bonding layer 82 and the bonding layer 182 are dielectric-to-dielectric (e.g., oxide-to-oxide) bonds, or the like. The bonding process also directly bonds the bonding pads 84 to the bonding pads 184 through direct metal-to-metal bonding. Thus, electrical connection between the integrated circuit die 50C and the integrated circuit die 150C is provided by the physical and electrical connection of the bonding pads 84 and the bonding pads 184. In some embodiments, the interface also includes dielectric-to-metal interfaces between the integrated circuit dies 50C/150C (e.g., where the bonding pads 84 and the bonding pads 184 are not perfectly aligned and/or have different widths).

Moreover, the interface between the integrated circuit dies 50C/150C includes metal-to-metal bonds between the solder pillar 190 and the bonding pad 84E of the integrated circuit die 50C. As discussed in greater detail below, during the bonding process, the solder pillar 190 is reflowed, which may cause the solder pillar 190 to spread out on contact with the integrated circuit die 50C. As a result, the flattened solder pillar 190 directly interposes the bonding pads 84/184. In some embodiments, the flattened solder pillar 190 may fill the recess 174R above the bonding pad 184E and, therefore, fill a region directly interposing the bonding pads 84E/184E. For example, the flattened solder pillar 190 may remain within that region or may spread out further than the bonding pads 84/184 and, therefore, directly interpose portions of the bonding layers 82/182. In other embodiments, the flattened solder pillar 190 may partially fill that region thereby leaving a void or voids between the bonding pads 84E/184E.

Still referring to FIGS. 11 and 12 and similarly as described above, the bonding process may start with a surface treatment and cleaning process performed on the integrated circuit dies 50C/150C. Next, the bonding process proceeds by aligning the bonding pads 84 to the bonding pads 184. When the integrated circuit dies 50C/150C are aligned, the bonding pads 84 may overlap with the corresponding bonding pads 184. After alignment, the integrated circuit dies 50C/150C are moved toward one another (e.g., the integrated circuit die 50C is moved downward toward the integrated circuit die 150C). In some embodiments, before moving the integrated circuit die 50C, a heat may be applied to soften or partially reflow the solder pillar 190, which may change shape or remain in substantially the same shape. As the integrated circuit dies 50C/150C move closer to one another, electrostatic charges on one or both may cause electric discharge between the two components. As discussed above, the electrostatic charges may have accumulated during previous processing steps, such as during the singulation of the integrated circuit dies 50C.

The solder pillar 190 serves as a lightning conductor with the bonding pad 84E to route the electrostatic discharge to the ESD wells 170 of the integrated circuit die 150C and the ESD wells 70 of the integrated circuit die 50C. Similarly, the bonding pad 84E may also serve as a lightning conductor due to bowing of the integrated circuit die 50C causing the bonding pad 84E to be the closest conductive feature to the solder pillar 190 of the integrated circuit die 150C during approach. As the integrated circuit dies 50C/150C move closer, the solder pillar 190 of the integrated circuit die 150C is first to make physical contact with the bonding pad 84E of the integrated circuit die 50C. As the integrated circuit dies 50C/150C continue moving toward one another, the solder pillar 190 flattens and spreads out along the bonding pads 84E/184E. In accordance with some embodiments, the solder pillar 190 has a volume substantially the same as a volume of the recess 174R and, therefore, fills the recess 174R without excess after the bonding process is complete. As a result, the bonding layers 82/182 and the bonding pads 84/184 may form a substantially seamless interface when the integrated circuit die 50C is bonded to the integrated circuit die 150C.

The bonding includes a pre-bonding step, during which the integrated circuit die 50C is put in contact first with the solder pillar 190 and, next, with the bonding layer 182 and the bonding pads 184. The integrated circuit die 50C may be secured to a chuck by a vacuum or any suitable means, similarly as described above in connection with the integrated circuit dies 50A/50B. In addition, a pin may press against the back side of the integrated circuit die 50C to cause a bowing toward the integrated circuit die 150C. The pre-bonding may be performed at room temperature (e.g., between about 21° C. and about 25° C.). The bonding process continues with performing an anneal, for example, at a temperature between about 150° C. and about 400° C. for a duration between about 0.5 hours and about 3 hours, so that the metal of the bonding pads 84 (e.g., copper) and the metal of the bonding pads 184 (e.g., copper) inter-diffuses with each other, and hence the direct metal-to-metal bonding is formed. Other direct bonding processes (e.g., using adhesives, polymer-to-polymer bonding, or the like) may be used in other embodiments. Notably, the solder pillar 190 connections with the bonding pads 84E/184E assist in the bonding of the integrated circuit die 50C to the integrated circuit die 150C.

As discussed above, the solder pillar 190 may be deposited at a volume such that the flattened solder pillar 190 fills the dish shape (e.g., the recess 174R) of the bonding pad 184E without excess. In other embodiments, the flattened solder pillar 190 partially fills or over fills the dish shape of the bonding pad 184E. In any case, after the bonding process, the flattened solder pillar 190 is directly interposed and may be in physical contact with both of the bonding pads 84E/184E. As a result, the ESD wells 70 maintain electrical connection with the ESD wells 170 to continue assisting in charge balancing if necessary. As discussed above, the flattened solder pillar 190 may improve adhesion of the integrated circuit dies 50C/150C with stronger bonds with each of the bonding pads 84E/184E.

Following the attachment process, the semiconductor package may undergo further processing (not specifically illustrated). For example, a gap-fill material may be formed over and between adjacent integrated circuit dies 50C, additional semiconductor components may be attached to the semiconductor package, external connectors may be formed, and/or the semiconductor package may be attached to a package substrate. At any stages, the structure may undergo additional testing (e.g., thermal cycle testing).

FIGS. 13 through 18 illustrate embodiments in which the bonding pads 84E/184E serve as lightning conductors to provide the electrostatic discharge benefits described above. For example, integrated circuit dies 50D/150D are formed to include bonding pads 84E/184E being electrically connected to the respective ESD wells 70/170 without forming a conductive pillar 186, a solder ball 188, or a solder pillar 190 thereon. As such, the bonding pads 84E/184E may be referred to as planar lightning conductors. As discussed in greater detail below, a bowing of the integrated circuit die 50D may be induced such that the bonding pad(s) 84E effectively protrude from the integrated circuit die 50D.

FIG. 13 illustrates a cross-sectional view of an intermediate stage of bonding an integrated circuit die 50D to an integrated circuit die 150D. The integrated circuit dies 50D/150D were fabricated, similarly as described above, up through formation of the bonding pads 84/184 (e.g., including the bonding pads 84E/184E). As discussed above, during the bonding sub-step of moving the integrated circuit die 50D may be secured to a chuck (not specifically illustrated) while moving toward the integrated circuit die 150D. In addition, a pin 192 may press the back side of the integrated circuit die 50D to cause a bowing toward the integrated circuit die 150D during the approach. As a result, a central region 51 (e.g., a bowing region) of the integrated circuit die 50D is most proximal to the integrated circuit die 150D before the components make physical contact with one another. Similarly as discussed above, electrostatic charges that have accumulated on either or both components may discharge between the integrated circuit dies 50D/150D when the components are sufficiently close to one another. In accordance with the present embodiments, the electrostatic discharge occurs between the bonding pads 84E/184E that are located or have portions located in the respective central regions 51 of the integrated circuit dies 50D/150D (e.g., the central region 51 of the integrated circuit die 50D and a corresponding region of the integrated circuit die 150D).

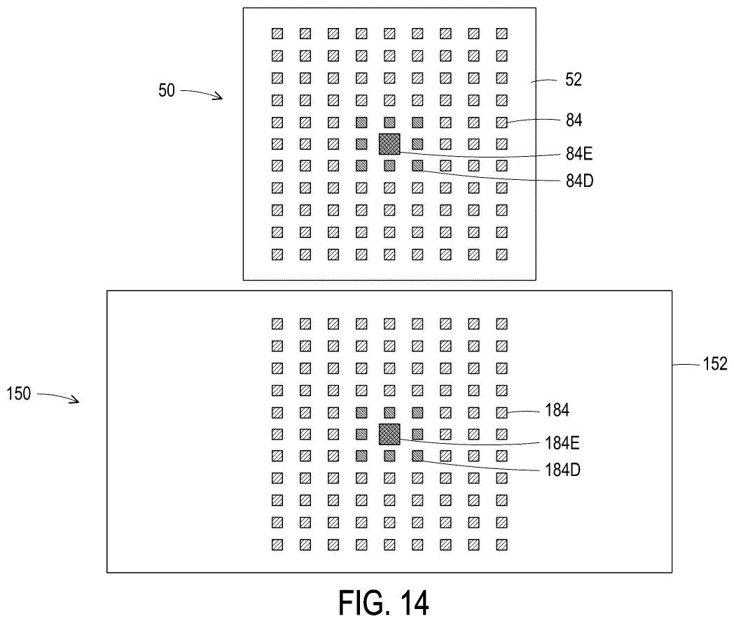

FIGS. 14 through 18 provide plan views of the integrated circuit dies 50D/150D to illustrate various layouts (e.g., shapes, sizes, and locations) of the bonding pads 84E/184E, in accordance with various embodiments. The various layouts are designed such that at least one bonding pad 84E or a portion of at least one bonding pad 84E is located in the bowing region of the integrated circuit die 50D. In some embodiments, dummy bonding pads 84D/184D may be formed adjacent to the bonding pads 84E/184E for structural integrity and to provide a buffer region between the bonding pads 84E/184E and the other bonding pads 84/184 which are electrically connected to their respective integrated circuits.

FIG. 14 illustrates plan views of a first set of exemplary integrated circuit dies 50D/150D having layouts that direct electrostatic discharge to the bonding pads 84E/184E, in accordance with some embodiments. For example, the integrated circuit die 50D may include a single bonding pad 84E located in a central region 51. As discussed above, the central region 51 may bow outward as the integrated circuit die 50D is moved toward the integrated circuit die 150D. In addition, the integrated circuit die 150D may include a single corresponding bonding pad 184E aligned with the bonding pad 84E during and after the bonding process. Throughout the bonding sub-step of FIG. 13, the most proximal points of the integrated circuit dies 50D/150D are the bonding pads 84E/184E. Due to comprising conductive material and being electrically connected to the ESD wells 70/170, the bonding pads 84E/184E serve as lightning conductors to discharge electrostatic charge that may have accumulated on either or both of the integrated circuit dies 50D/150D.

As illustrated, the bonding pads 84E/184E may have greater widths than the other bonding pads 84/184 (e.g., electrically connected to the respective integrated circuits) to increase the likelihood of receiving any electrostatic discharge and preventing electrostatic discharge with those other bonding pads 84/184. The greater width better ensures that this benefit is achieved whether the integrated circuit dies 50D/150D are aligned or misaligned. In some embodiments, the bonding pads 84E/184E have substantially the same widths as the other bonding pads 84/184. For example, the bonding pads 84E/184E may have any suitable width equal to or greater than the width of the other bonding pads 84/184, such as being up to two times or three times greater. In addition, the bonding pads 84E/184E may have a same shape or different shape as the other bonding pads 84/184, including oval (e.g., circular) or rectangular (e.g., square).

Optionally and as discussed above, dummy bonding pads 84D/184D may separate the bonding pads 84E/184E from the other bonding pads 84/184 (e.g., electrically connected to the respective integrated circuits). As such, the dummy bonding pads 84D/184D help to prevent electrostatic discharge to any of those other bonding pads 84/184. The dummy bonding pads 84D/184D also provide additional regions of metal-to-metal bonding between the integrated circuit dies 50D/150D. In some embodiments (not specifically illustrated), each of the dummy bonding pads 84D/184D may comprise a continuous conductive material (e.g., a ring) around the bonding pads 84E/184E.

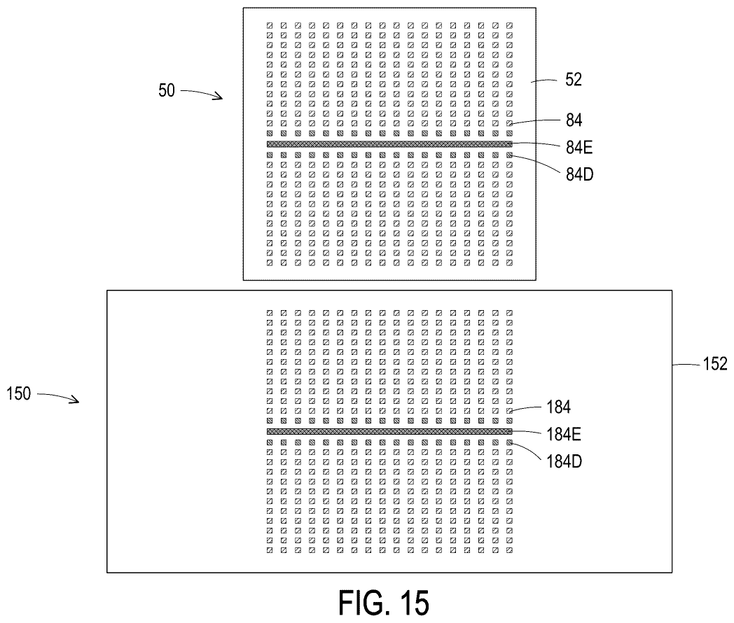

FIG. 15 illustrates plan views of a second set of exemplary integrated circuit dies 50D/150D having layouts that direct electrostatic discharge to the bonding pads 84E/184E, in accordance with some embodiments. For example, the integrated circuit die 50D may include a single bonding pad 84E comprising a line segment extending across a majority of the integrated circuit die 50D and through the central region 51. In addition, the integrated circuit die 150D may include a single corresponding bonding pad 184E aligned with the bonding pad 84E during and after the bonding process. Throughout the bonding sub-step of FIG. 13, the most proximal points of the integrated circuit dies 50D/150D include portions of the bonding pads 84E/184E, which therefore serve as lightning conductors to discharge accumulated electrostatic charge.

As illustrated, the bonding pads 84E/184E may have substantially the same widths as the other bonding pads 84/184 (e.g., electrically connected to the respective integrated circuits). The much longer lengths of the bonding pads 84E/184E achieve the benefit of increasing the likelihood of receiving any electrostatic discharge and preventing discharge with those other bonding pads 84/184. In some embodiments, the bonding pads 84E/184E may have greater widths than the other bonding pads 84/184 in order to better ensure that this benefit is achieved, e.g., whether the integrated circuit dies 50D/150D are aligned or misaligned. The bonding pads 84E/184E and the other bonding pads 84/184 of this embodiment may have any of the relative widths and shapes as described above in connection with FIG. 14.

Optionally and as discussed above, dummy bonding pads 84D/184D may provide buffer regions between the bonding pads 84E/184E and the other bonding pads 84/184 (e.g., electrically connected to the respective integrated circuits) for the purposes and benefits described above. In some embodiments (not specifically illustrated), the dummy bonding pads 84D/184D are continuous line segments extending along each side of the bonding pads 84E/184E and parallel thereto.

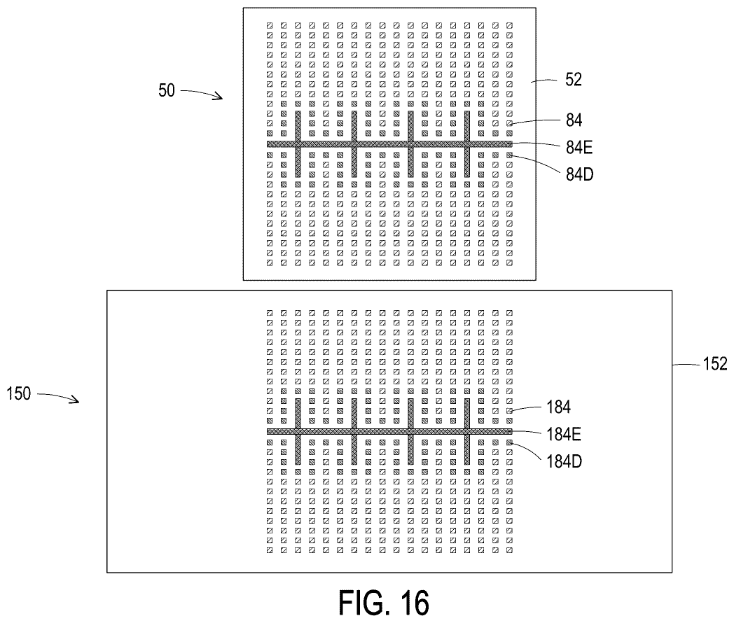

FIG. 16 illustrates plan views of a third set of exemplary integrated circuit dies 50D/150D having layouts that direct electrostatic discharge to the bonding pads 84E/184E, in accordance with some embodiments. For example, the integrated circuit die 50D may include one or more cross shapes, which comprise a main line segment (e.g., a first axis) as described in connection with FIG. 15 in conjunction with one or more perpendicular line segments (e.g., a second axis). In some embodiments, at least one of the perpendicular line segments may also extend through the central region 51. In other embodiments, the central region 51 includes a portion of the main line segment and is free of the perpendicular line segments. In addition, the integrated circuit die 150D may include a corresponding bonding pad 184E having a same shape to be aligned with the bonding pad 84E. Note that the perpendicular line segments are illustrated as extending for a minority of a width of the integrated circuit die 50D (or of a bonding pad region thereof), however the perpendicular line segments may extend for a majority or an entirety of that width. Throughout the bonding sub-step of FIG. 13, the most proximal points of the integrated circuit dies 50D/150D include portions of the bonding pads 84E/184E, which therefore serve as lightning conductors to discharge accumulated electrostatic charge. The perpendicular line segments achieve the benefit of increasing the likelihood of the bonding pads 84E/184E receiving any electrostatic discharge whether aligned or misaligned, or when warpage of either or both of the integrated circuit dies 50D/150D causes the most proximal point(s) to be outside of the central region 51.

As illustrated, the bonding pads 84E/184E may have substantially the same widths as the other bonding pads 84/184 (e.g., electrically connected to the respective integrated circuits). In some embodiments, the bonding pads 84E/184E (e.g., the main line segments and/or the perpendicular line segments) may have greater widths than the other bonding pads 84/184 in order to better ensure that this benefit is achieved, e.g., whether the integrated circuit dies 50D/150D are aligned or misaligned. The bonding pads 84E/184E (e.g., either or both types of segments) and the other bonding pads 84/184 of this embodiment may have any of the relative widths and shapes as described above in connection with FIG. 14.

Optionally and as discussed above, dummy bonding pads 84D/184D may provide buffer regions between the bonding pads 84E/184E and the other bonding pads 84/184 (e.g., electrically connected to the respective integrated circuits) for the purposes and benefits described above. As illustrated, the dummy bonding pads 84D/184D may circumscribe (e.g., generally outline) the pattern of the bonding pads 84E/184E. In some embodiments (not specifically illustrated), the dummy bonding pads 84D/184D include continuous portions extending around and along the bonding pads 84E/184E.

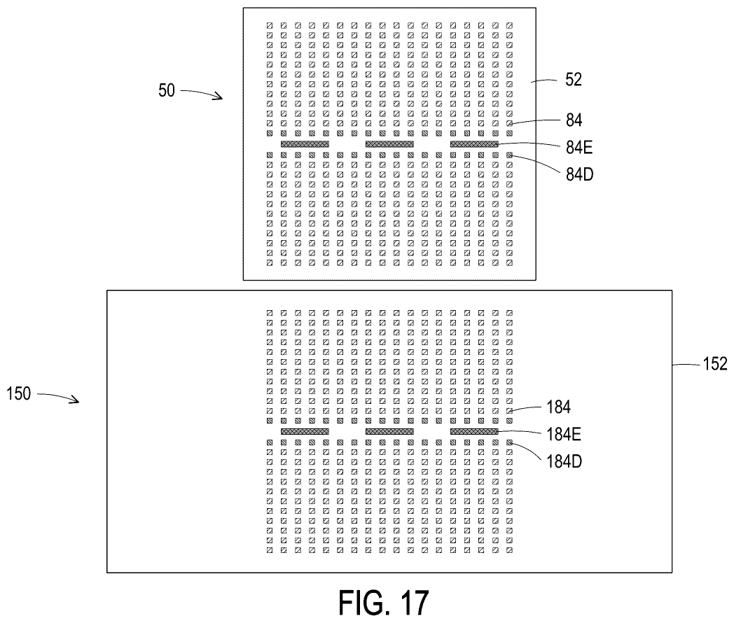

FIG. 17 illustrates plan views of a fourth set of exemplary integrated circuit dies 50D/150D having layouts that direct electrostatic discharge to the bonding pads 84E/184E, in accordance with some embodiments. For example, the integrated circuit die 50D may include a plurality of line segments extending linearly across most of the integrated circuit die 50D and through the central region 51, analogously as described above in connection with FIG. 15. In some embodiments, at least one of the main line segments may also extend through the central region 51. In other embodiments, the central region 51 includes portions of two main line segments. In addition, the integrated circuit die 150D may include corresponding bonding pads 184E having same shapes and locations to be aligned with the bonding pads 84E. The bonding pads 84E/184E of this embodiment achieve similar benefits as those discussed above in connection with FIG. 15. By utilizing a plurality of line segments for the bonding pads 84E/184E, the bonding between the integrated circuit dies 50D/150D may be stronger and more reliable even in cases of warpage or misalignment of the bonding pads 84E/184E. For example, the bonded semiconductor package may be less vulnerable to detachment or delamination.

As illustrated, the bonding pads 84E/184E may have substantially the same widths as the other bonding pads 84/184 (e.g., electrically connected to the respective integrated circuits). The longer lengths of the bonding pads 84E/184E achieve the benefit of increasing the likelihood of receiving any electrostatic discharge and preventing discharge with those other bonding pads 84/184. In some embodiments, the bonding pads 84E/184E may have greater widths than the other bonding pads 84/184 in order to better ensure that this benefit is achieved, e.g., whether the integrated circuit dies 50D/150D are aligned or misaligned. The bonding pads 84E/184E and the other bonding pads 84/184 of this embodiment may have any of the relative widths and shapes as described above in connection with FIG. 14.

Optionally and as discussed above, dummy bonding pads 84D/184D may provide buffer regions between the bonding pads 84E/184E and the other bonding pads 84/184 (e.g., electrically connected to the respective integrated circuits) for the purposes and benefits described above. In some embodiments (not specifically illustrated), the dummy bonding pads 84D/184D include a plurality of continuous line segments extending parallel to and along each side of the bonding pads 84E/184E. Optionally, additional dummy bonding pads 84D/184D may be located between the bonding pads 84E/184E.

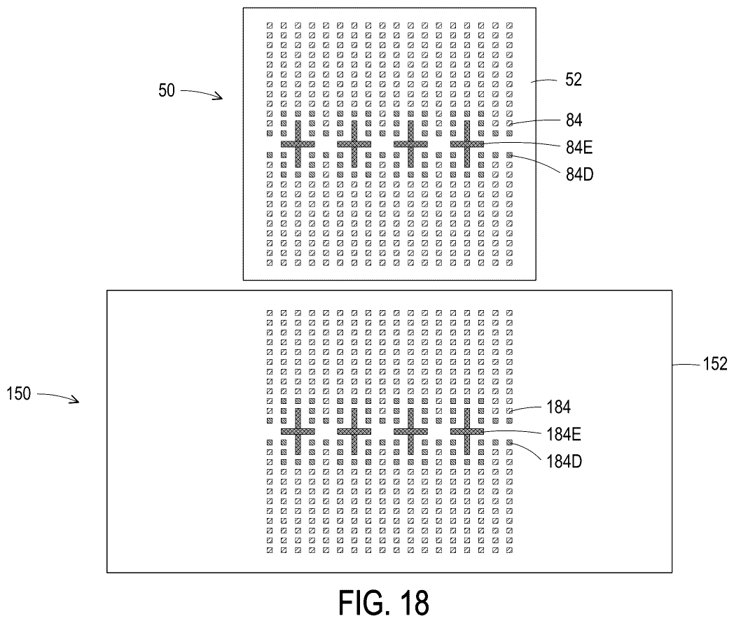

FIG. 18 illustrates plan views of a fifth set of exemplary integrated circuit dies 50D/150D having layouts that direct electrostatic discharge to the bonding pads 84E/184E, in accordance with some embodiments. For example, the integrated circuit die 50D may include one or more cross shapes, which comprise a plurality of main line segments as described in connection with FIG. 17 in conjunction with corresponding perpendicular line segments as described in connection with FIG. 16. In some embodiments, at least one of main line segments extends through the central region 51. Among such embodiments, at least one of the perpendicular line segments may also extend through the central region 51. In other embodiments, the central region 51 includes portions of two main line segments and is free of the perpendicular line segments. In addition, the integrated circuit die 150D may include corresponding bonding pads 184E having same shapes and locations to be aligned with the bonding pads 84E. The bonding pads 84E/184E of this embodiment achieve similar benefits as those discussed above in connection with FIG. 16. By utilizing a plurality of main line segments for the bonding pads 84E/184E, the bonding between the integrated circuit dies 50D/150D may be stronger and more reliable even in cases of warpage or misalignment of the bonding pads 84E/184E. For example, the bonded semiconductor package may be less vulnerable to detachment or delamination.

As illustrated, the bonding pads 84E/184E may have substantially the same widths as the other bonding pads 84/184 (e.g., electrically connected to the respective integrated circuits). The longer lengths of the bonding pads 84E/184E achieve the benefit of increasing the likelihood of receiving any electrostatic discharge and preventing discharge with those other bonding pads 84/184. In some embodiments, the bonding pads 84E/184E may have greater widths than the other bonding pads 84/184 in order to better ensure that this benefit is achieved, e.g., whether the integrated circuit dies 50D/150D are aligned or misaligned. The bonding pads 84E/184E and the other bonding pads 84/184 of this embodiment may have any of the relative widths and shapes as described above in connection with FIG. 14.

Optionally and as discussed above, dummy bonding pads 84D/184D may provide buffer regions between the bonding pads 84E/184E and the other bonding pads 84/184 (e.g., electrically connected to the respective integrated circuits) for the purposes and benefits described above. As illustrated, the dummy bonding pads 84D/184D may circumscribe the patterns of the bonding pads 84E/184E. In some embodiments (not specifically illustrated), the dummy bonding pads 84D/184D include continuous portions extending around and along each side of the bonding pads 84E/184E. Optionally, additional dummy bonding pads 84D/184D may be located between the bonding pads 84E/184E.

In FIG. 8, a singulation process is performed by sawing along scribe line regions, e.g., between the first package region 100A and the second package region 100B. The sawing singulates the first package region 100A from the second package region 100B. The resulting, singulated device 100 is from one of the first package region 100A or the second package region 100B.

In FIG. 9, each singulated first package component 100 may be mounted to a package substrate 200 using the conductive connectors 124. The package substrate 200 includes a substrate core 202 and bond pads 204 over the substrate core 202. The substrate core 202 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 202 may be an SOI substrate. Generally, an SOI substrate includes a layer of a semiconductor material such as epitaxial silicon, germanium, silicon germanium, SOI, SGOI, or combinations thereof. The substrate core 202 is, in one alternative embodiment, based on an insulating core such as a fiberglass reinforced resin core. One example core material is fiberglass resin such as FR4. Alternatives for the core material include bismaleimide-triazine (BT) resin, or alternatively, other PCB materials or films. Build up films such as ABF or other laminates may be used for substrate core 202.

The substrate core 202 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 202 may also include metallization layers and vias (not shown), with the bond pads 204 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 202 is substantially free of active and passive devices. Conductive connectors 210 (e.g., ball grid array (BGA) balls, or the like) may be disposed on a surface of the substrate core 202 opposite the first package component 100. The conductive connectors 210 may allow the package substrate 200 to be attached to another component, such as, a motherboard, a printed circuit board (PCB), or the like.

In some embodiments, the conductive connectors 124 are reflowed to attach the first package component 100 to the bond pads 204. The conductive connectors 124 electrically and/or physically couple the package substrate 200, including metallization layers in the substrate core 202, to the first package component 100. In some embodiments, a solder resist 206 is formed on the substrate core 202. The conductive connectors 124 may be disposed in openings in the solder resist 206 to be electrically and mechanically coupled to the bond pads 204. The solder resist 206 may be used to protect areas of the substrate 202 from external damage.

The conductive connectors 124 may have an epoxy flux (not shown) formed thereon before they are reflowed with at least some of the epoxy portion of the epoxy flux remaining after the first package component 100 is attached to the package substrate 200. This remaining epoxy portion may act as an underfill to reduce stress and protect the joints resulting from reflowing the conductive connectors 124. In some embodiments, an underfill 208 may be formed between the first package component 100 and the package substrate 200 and surrounding the conductive connectors 124. The underfill 208 may be formed by a capillary flow process after the first package component 100 is attached or may be formed by a suitable deposition method before the first package component 100 is attached. Thus, a package 300A is formed comprising the first package component 100 and the package substrate 200.

The first package component 100 may be implemented in other device stacks. For example, a chip on wafer on substrate structure is shown, but the first package component 100 may also be implemented in a Package on Package (POP) configuration (e.g., with an integrated fan-out (InFO) configuration), a Flip Chip Ball Grid Array (FCBGA) package, or the like. Optionally, a lid or heat spreader (not specifically illustrated) may be attached to a surface of the first package component 100 opposite to the substrate.

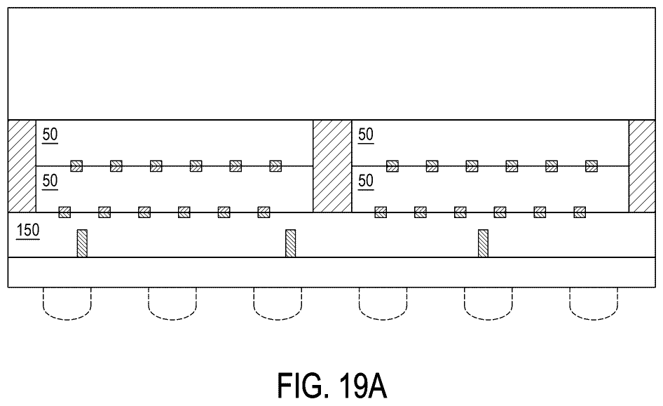

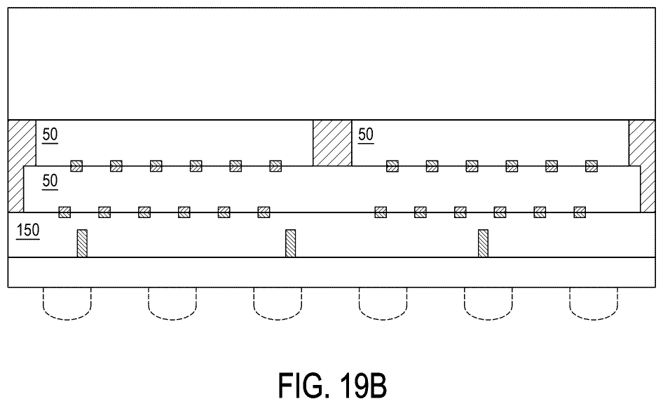

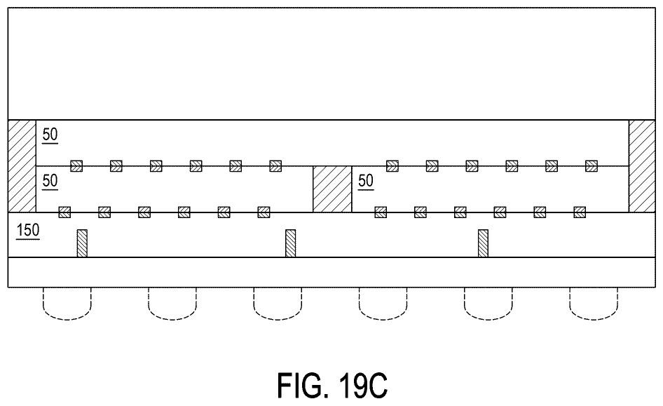

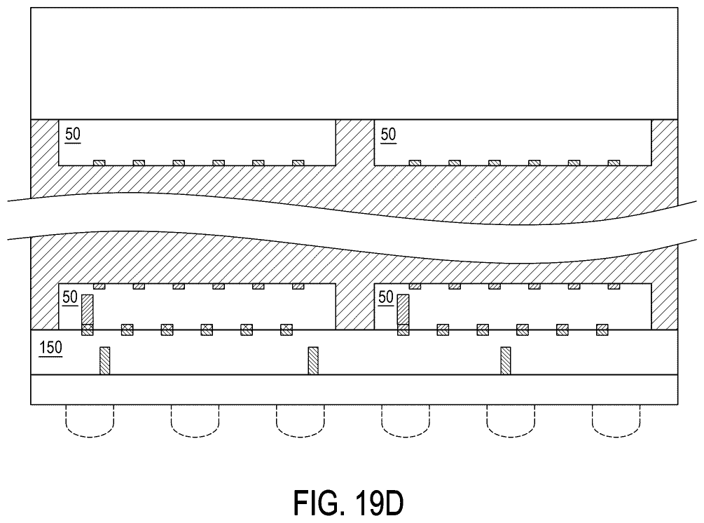

FIGS. 19A through 19D illustrate various packaging structures that may utilize the embodiments disclosed herein. In addition, multiple versions of the lightning conductors may be utilized in a semiconductor package. For example, attaching middle integrated circuit dies 50 to the integrated circuit die 150 (e.g., wafer) may include protruding lightning structures (see FIGS. 1A through 12), while attaching top integrated circuit dies 50 to the middle integrated circuit dies 50 may include planar lightning conductors which protrude during the bonding process until making physical contact (see FIGS. 13 through 18). However, any suitable combinations may be utilized.

FIG. 19A illustrates packaging a multi-chip layer (e.g., integrated circuit dies 50) on a multi-chip layer (e.g., integrated circuit dies 50) on a wafer layer (e.g., integrated circuit die 150). FIG. 19B illustrates packaging a multi-chip layer (e.g., integrated circuit dies 50) on a single-chip layer (e.g., integrated circuit die 50) on a wafer layer (e.g., integrated circuit die 150). FIG. 19C illustrates packaging a single-chip layer (e.g., integrated circuit die 50) on a multi-chip layer (e.g., integrated circuit dies 50) on a wafer layer (e.g., integrated circuit die 150). FIG. 19D illustrates packaging multi-chip multi-layers (e.g., integrated circuit dies 50) on a wafer layer (e.g., integrated circuit die 150), however any number of the multi-layers may be single-chip layers.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Various advantages are achieved. In particular, directing electrostatic discharge to the lightning conductors (e.g., the bonding pads 84E/184E and associated conductive features, if present) prevents or reduces damage to the integrated circuit from electrostatic discharge to other conductive features (e.g., other bonding pads 84/184). The lightning conductors are designed so that electrostatic discharge is concentrated at or directed to the lightning conductors due to a phenomenon called the sharp point effect. As a result, semiconductor packages may be manufactured with greater yield and with improved performance. In addition, the integrated circuit dies 50/150 of the semiconductor packages may be fabricated with more semiconductor substrate area devoted to features of the integrated circuit and less area devoted to electrostatic discharge wells and portions of the interconnect structure connecting to the electrostatic discharge wells. Further, the integrated circuit dies 50/150 may be fabricated with few or zero additional steps in the formation of the various types of lightning conductors.

In an embodiment, a method includes: forming a first integrated circuit die, the first integrated circuit die comprising: a first active device along a first substrate; a first electrostatic discharge well along the first substrate; a first bonding pad over the first substrate and electrically connected to the first active device; and a first lightning conductor over the first substrate and electrically connected to the first electrostatic discharge well; forming a second integrated circuit die, the second integrated circuit die comprising: a second active device along a second substrate; a second electrostatic discharge well along the second substrate; a second bonding pad over the second substrate and electrically coupled to the second active device; and a second lightning conductor over the second substrate and electrically connected to the second electrostatic discharge well; and bonding the first integrated circuit die to the second integrated circuit die. In another embodiment, the bonding comprises: moving the first integrated circuit die toward the second integrated circuit die resulting in an electrostatic discharge between the first lightning conductor and the second lightning conductor; and bonding the first bonding pad directly to the second bonding pad. In another embodiment, the method further includes singulating the first integrated circuit die from a wafer, wherein the singulating comprises accumulating positive charges on the first integrated circuit die. In another embodiment, during the moving the first integrated circuit die: a pin causes the first integrated circuit die to bow toward the second integrated circuit die; and the first lightning conductor and the second lightning conductor are most proximal components between the first integrated circuit die and the second integrated circuit die. In another embodiment, each of the first lightning conductor and the second lightning conductor is shaped as a line segment or a cross. In another embodiment, the first lightning conductor comprises an opening in a first surface of the first integrated circuit die, wherein the opening has a depth, wherein the second lightning conductor comprises a conductive feature protruding from a second surface of the second integrated circuit die, and wherein the conductive feature has a height. In another embodiment, the depth is greater than or equal to the height. In another embodiment, the first lightning conductor comprises a third bonding pad, and wherein the second lightning conductor comprises a fourth bonding pad and a conductive feature disposed on the fourth bonding pad. In another embodiment, bonding the first integrated circuit die to the second integrated circuit die comprises flattening the conductive feature between the third bonding pad and the fourth bonding pad. In another embodiment, the fourth bonding pad has a dish shape, and wherein after bonding the first integrated circuit die to the second integrated circuit die, an entirety of the conductive feature is contained within a space between the third bonding pad and the fourth bonding pad.

In an embodiment, a semiconductor die includes: an active device along a front side of a semiconductor substrate; an electrostatic discharge well along the front side of the semiconductor substrate; an interconnect structure over the semiconductor substrate; a dielectric layer over the interconnect structure; a bonding pad embedded in the dielectric layer, the bonding pad being electrically connected to the active device; and an electrostatic discharge conductor embedded in the dielectric layer, the electrostatic discharge conductor being electrically connected to the electrostatic discharge well, wherein the electrostatic discharge conductor comprises a furthest protruding point from a back side of the semiconductor die, wherein the electrostatic discharge conductor is along a bonding side of the semiconductor die, and wherein the bonding side faces opposite of the back side. In another embodiment, the electrostatic discharge conductor comprises a conductive pillar disposed on an additional bonding pad. In another embodiment, the conductive pillar comprises solder. In another embodiment, the additional bonding pad is a recessed bonding pad. In another embodiment, the electrostatic discharge conductor is another bonding pad having a cross shape, wherein a major axis of the cross shape extends across a majority of the semiconductor die.

In an embodiment, a semiconductor package includes: a first active device along a first substrate; a first electrostatic discharge well along the first substrate; a first interconnect structure over the first active device and the first electrostatic discharge well; a first bonding pad over the first interconnect structure and electrically connected to the first active device; a first lightning conductor over the first interconnect structure and electrically connected to the first electrostatic discharge well; a second bonding pad over and directly bonded to the first bonding pad; a second lightning conductor over and directly bonded to the first lightning conductor; a second interconnect structure over the second bonding pad and the second lightning conductor; a second active device over the second interconnect structure and electrically connected to the second bonding pad; and a second electrostatic discharge well over the second interconnect structure and electrically connected to the second lightning conductor. In another embodiment, the first lightning conductor comprises a third bonding pad and a flattened solder material. In another embodiment, the third bonding pad is recessed in comparison to the first bonding pad. In another embodiment, each of the first lightning conductor and the second lightning conductor comprises a main line segment and one or more perpendicular line segments. In another embodiment, each of the first lightning conductor and the second lightning conductor comprises a plurality of cross shapes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first integrated circuit die, forming the first integrated circuit die comprising:
forming an active device along a front side of a semiconductor substrate;
forming a first electrostatic discharge well along the front side of the semiconductor substrate;
forming an interconnect structure over the semiconductor substrate, the interconnect structure comprising a metal pad;
forming a first dielectric layer over the interconnect structure; and
forming an opening in the first dielectric layer to expose the metal pad, the metal pad being electrically connected to the first electrostatic discharge well;
providing a second integrated circuit die, the second integrated circuit die comprising an electrostatic discharge conductor extending from a bonding pad of the second integrated circuit die, the bonding pad being embedded in a second dielectric layer; and
bonding the second integrated circuit die to the first integrated circuit die, wherein before completion of the bonding the second integrated circuit die to the first integrated circuit die the electrostatic discharge conductor is capable of electrostatic discharge with the metal pad.

2. The method of claim 1, wherein the electrostatic discharge conductor is along a bonding side of the second integrated circuit die, wherein the electrostatic discharge conductor comprises a furthest protruding point from a back side of the second integrated circuit die, and wherein the bonding side faces opposite of the back side.
